(19) United States
(12) Patent Application Publication
(10) Pub. No.: US 2005/0275570 A1
(43) Pub. Date: Dec. 15, 2005

(54) Parallel leading bit detection for Exp-Golomb decoding

(76) Inventor: Wen-shan (Vincent) Wang, Chandler, AZ (US)

Correspondence Address: INTEL CORPORATION, P.O. BOX 5326, SANTA CLARA, CA, 95056-5326, US

(21) Appl. No.: 10/868,456

(22) Filed: Jun. 10, 2004

(51) Int. Cl. H03M 7/40; H03M 7/00

(52) U.S. Cl. 341/65

(57) ABSTRACT

A system may include a number of detectors and a processor. Each detector may be arranged to receive a different number of N leading bits. Each detector may output an affirmative feedback bit if the different number of N leading bits matches a respective predetermined pattern. The processor may provide the N leading bits to the number of detectors and may receive a corresponding number of feedback bits. The processor may also determine an Exponential Golomb code number based on the number of feedback bits.

### BACKGROUND

Implementations of the claimed invention generally may relate to decoding variable-length codes and, more particularly, to decoding Exponential Golomb (Exp-Golomb) codes.

Exp-Golomb codes are variable length codes of a regular construction. Exp-Golomb codes are widely used in the Advanced Video Coding (AVC) (e.g., H.264 and/or MPEG-4, Part 10). Similar to other variable-length codes (e.g., Huffman code), decoding Exp-Golomb codes may be somewhat difficult, because the input data length is varied and unpredictable.

FIG. 1 includes a table 100 that lists the first 10 code words of an Exp-Golomb code and their corresponding code numbers. As may be observed from table 100, all of individual codes of a given Exp-Golomb code set are unique. Also, the n most significant bits (MSBs) of a given code are different from any other code having length of n. Further, the Exp-Golomb code words consist of a number of “leading bits” followed by another number of value bits, the number of values bit being one less than that of the leading bits. The value bits may help specify the value of the particular code word. The leading bits of a code word contain a number of leading 0 bits followed by one 1 bit. The number of leading 0 bits is the same as that of the value bits for the code word. Finally, if the leading bit length is 1, there are no leading 0 and value bit for that code word.

One proposed scheme for decoding Exp-Golomb codes, defined in an AVC standard (i.e., ISO/IEC FDIS 14496-10), may serially search leading bits to decode the Exp-Golomb code. Because the length of the incoming code word is unknown and unpredictable, such a serial decoding scheme may read the leading 0 or 0's repeatedly until the first non-zero bit is received. Such a serial decoding scheme may check leading bits one by one and may take significant time for longer codes. Also for the serial scheme, the decoding time for a code word may vary depending on its code length.

Another proposed scheme for decoding Exp-Golomb codes may use table mapping to look up a code number corresponding to a given code word. In such a scheme, the number of entries the decoding table may equal 2^{(longest code length)}. For example, if the maximum code length is 7, then the table may have 128 entries, and longer code lengths implicate a larger memory size for the table.

### BRIEF DESCRIPTION OF THE DRAWINGS

The accompanying drawings, which are incorporated in and constitute a part of this specification, illustrate one or more implementations consistent with the principles of the invention and, together with the description, explain such implementations. The drawings are not necessarily to scale, the emphasis instead being placed upon illustrating the principles of the invention. In the drawings,

FIG. 1 illustrates example words and corresponding numbers of an Exp-Golomb code;

FIG. 2 illustrates an example system;

FIG. 3 illustrates an example output of the detectors in FIG. 2 for a particular series of leading bits; and

FIG. 4 is a flow chart illustrating a process of decoding an Exp-Golomb code.

### DETAILED DESCRIPTION

The following detailed description refers to the accompanying drawings. The same reference numbers may be used in different drawings to identify the same or similar elements. In the following description, for purposes of explanation and not limitation, specific details are set forth such as particular structures, architectures, interfaces, techniques, etc. in order to provide a thorough understanding of the various aspects of the claimed invention. However, it will be apparent to those skilled in the art having the benefit of the present disclosure that the various aspects of the invention claimed may be practiced in other examples that depart from these specific details. In certain instances, descriptions of well known devices, circuits, and methods are omitted so as not to obscure the description of the present invention with unnecessary detail.

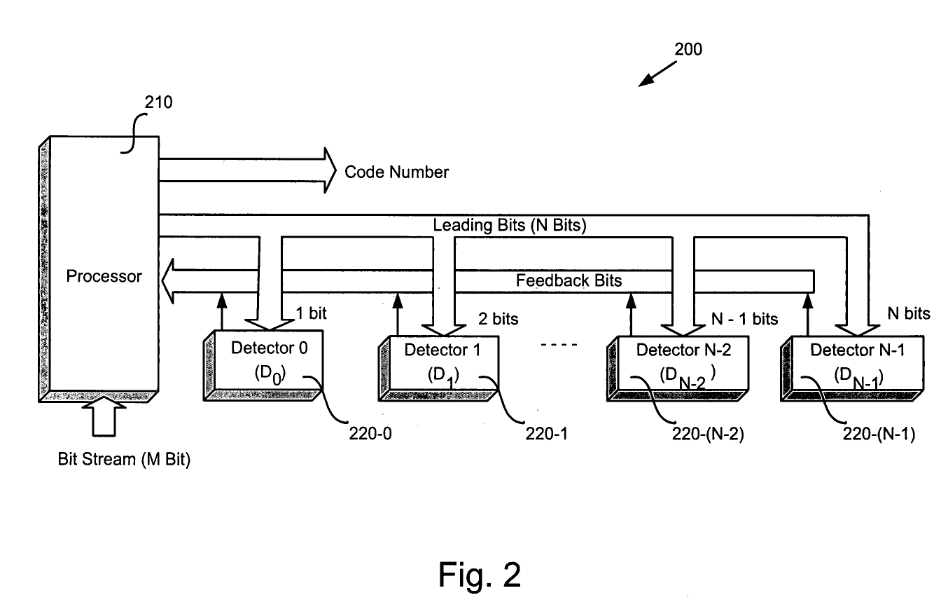

FIG. 2 illustrates an example system 200. System 200 may include a processor 210 and a number, N, of detectors 220-0, 220-1, . . . , 220-(N-1) (collectively “detectors 220”).

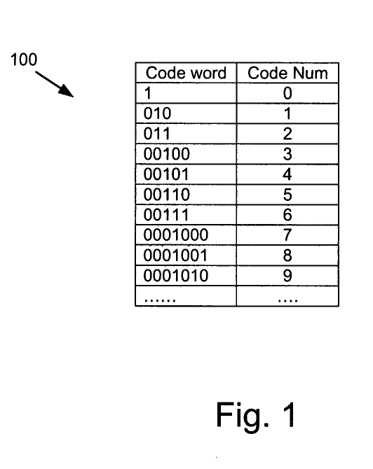

Processor 210 may include a general-purpose processor, a specific-purpose processor, and/or logic configured for a specific purpose. Although not explicitly illustrated in FIG. 1, processor 210 may include, or be associated with, a memory (e.g., buffer(s)) to temporarily store data during processing. Processor 210 may be arranged to distribute data from an input bit stream to detectors 220. Processor 210 may also be arranged to receive feedback bits from detectors 220.

During the course of operation, processor 210 may keep track of a current computing position within data from the input bit stream, for example via a pointer to the position. Processor 210 may be arranged to compute a code number based on the feedback from the detector 220 that finds valid leading bits for a given Exp-Golomb code. Although illustrated in FIG. 1 as outputting this code number, in some implementations processor 210 may use the code number internally for further processing tasks. Processor 210 may advance the bit stream pointer to the proper position upon determining the code number and the code length for the given Exp-Golomb code. Further operational details of processor 210 will be presented herein.

Detectors 220 may include logic arranged to perform specific detection and communication functions. Detectors 220 collectively may receive leading bits from processor 210 and may return feedback bit to processor 210. In some implementations, detectors 220 may communicate serially with processor 210. In some implementations, detectors 220 may communicate in parallel with processor 210. For example, processor 210 may output N leading bits in parallel, and detector 220-0 D₀ may be hardwired to receive the first one bit of these N bits. Detector 220-1 D₁ may receive the first two bits, and so on. The feedback bits from detectors 220 may be similarly aggregated into a parallel input to processor 210.

Each of detectors 220 may be logically arranged to output a 1 as its feedback bit if its last input bit is one and all other input bits (if present) are 0. Otherwise, detectors 220 may output a 0 as their respective feedback bits. Thus, only the detector 220 (e.g., the second detector 220-1) that detects a valid sequence of leading bits (e.g., 01) may output a 1, and the rest of the feedback bits from the other detectors 220 may be 0.

Detectors 220 may simultaneously detect for valid leading b its, and the one detector 220 finding the valid leading bits may trigger processor 210 to compute the Exp-Golomb code number, find the code length, and advance the bit-stream pointer appropriately. It should be noted that the number N of detectors 220 in system 200 may correspond to the maximum number N of leading bits that may be expected for a maximum expected Exp-Golomb code length M. The particular relationship between N and M will be further described herein.

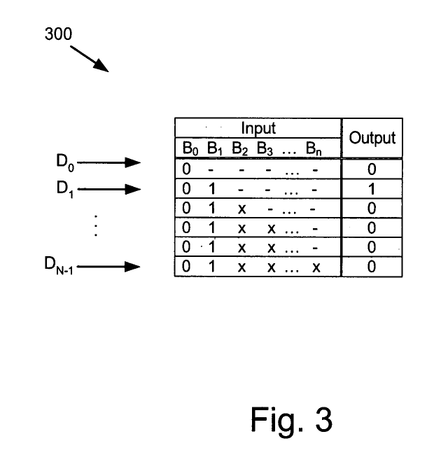

FIG. 3 illustrates an example truth table output 300 of detectors 220 for a particular series of leading bits B₀, B₁, . . . Bₙ. For the purposes of explanation, B₀ denotes the first leading bit, B₁ denotes the second leading bit, etc. Also, in table 300, “−” denotes that a certain detector (e.g., detector D₀) does not receive a given leading bit or bits (e.g., B₁, . . . Bₙ because in FIG. 2, detector D₀ only receives one bit. In table 300, “x” denotes a “don't care” bit.

Table 300 illustrates the output of the various detectors 220 to a leading bit stream of 01xxxxx. Detector D₀ does not output a 1, because the first leading bit is not a 1. By contrast, detector D₁ may output a 1, because the first leading bit is 0 and the second leading bit is 1. Subsequent detectors D₂ to D_{(N-1)} may output 0, because they have non-zero leading bit(s) (e.g., B₁) before their last leading bit.

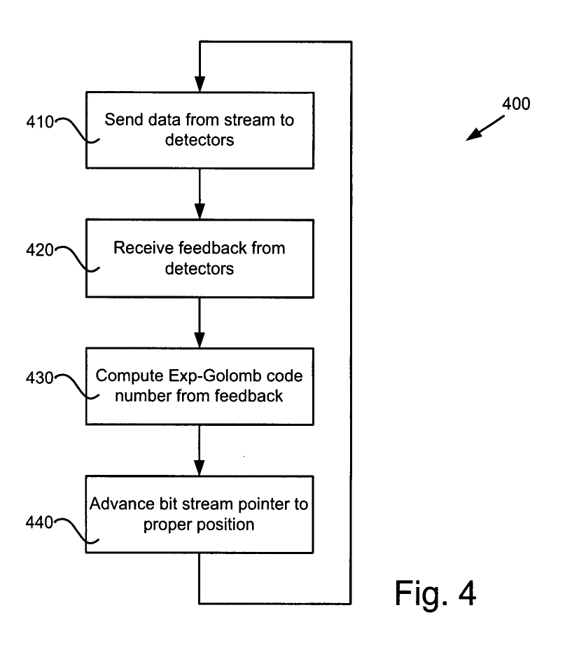

FIG. 4 is a flow chart illustrating a process 400 of process of decoding an Exp-Golomb code. Although process 400 may be described with regard to system 200 for ease of explanation, the claimed invention is not necessarily limited in this regard. With regard to process 200, M may denote the maximum code length of an Exp-Golomb code to be decoded by system 200. Also, N may denote the maximum number of leading bits of the Exp-Golomb code to be decoded. Mathematically, N=(M>>1)+1, where (M>>1) represents a right bit-shift of M by one bit. As an example, if the longest Exp-Golomb code length (i.e., M) is 7, then the longest leading bit length (i.e., N) is (3+1)=4.

Processing may begin with processor 210 bringing M bits of data from bit stream, without change the pointer from the end of the last code word. Processor 220 may supply up to N of these bits to leading-bit detectors 220 at the same time [act 410]. For example, detector 220-0 D₀ may receive the first bit, detector 220-1 D₁ may receive the first two bits, etc. Because of the nature of the Exp-Golomb code and the arrangement of detectors 220, only one of the detectors 220 D₀-D_{N-1} will find a valid leading bit or series of valid leading bits.

Processor 210 may receive feedback bits from each of detectors 220 [act 420]. Processor 210 may receive a triggering signal from the detector 220-n (Dₙ) that finds the valid leading bit(s). In some implementations, processor 210 may receive N parallel feedback bits from detectors 220, one of which is a 1 and the rest of which are 0. In some implementations, other signaling schemes may be used to alert processor 210 of the detector Dₙ that detects a valid string of leading bits.

Once processor 210 is triggered by detector Dₙ (and hence the leading bit length, n+1, is known), processor 210 may compute the corresponding Exp-Golomb code number [act 430]. In one scheme for computing, processor 210 may acquire the n value bits following the leading bits and may computing the code number as follows:
Code Number=(1<<n)−1+value bits
where (1<<n) denotes a left bit-shift of the value 1 by n bits. As noted previously, for Golomb code words, the n value bits following a 1 may help specify the code number in accordance with the above equation. Processor 210 may send the code number to another portion (not shown) of system 200 for further processing. In some implementations, however, processor 210 may perform further processing on the code number without sending it out.

Processor 210 may also advance the bit-stream pointer (or other mechanism for place holding in the input bit stream) to the proper beginning position for the next Exp-Golomb code word [act 440]. In some implementations, processor 210 may advance the pointer from its present position by ((n<<1)+1) bits, where (n<<1) denotes a left bit-shift of the value n by 1 bit. Once processor 210 has produced an Exp-Golomb code word and advanced the pointer appropriately, it may repeat acts 210-240 for the next M bits in the bit stream.

A brief numerical example will now be presented to aid in understanding FIGS. 2-4 and their description. The example will assume that M=7, N=4, and the bit stream is 000101010011001010 . . . , where the first bit is at the left end of this example bit stream. Processor 210 may obtain the first 7 bits, 0001010, and may send the first 4 of these, 0001, to detectors 220. 0 is received by D₀ detector 220-0; 00 is received by D₁ detector 220-1; 000 is received by D₂ detector 220-2; and 0001 is received by D₃ detector 220-3. Only D₃ detector 220-3 will detect valid leading bits, and the processor 210 may grab 3 value bits, 010 (i.e., 2 in decimal), compute the code number by ((1<<3)−1+2)=9, and advance the pointer by ((3<<1)+1)=7 bits to 10011001010 . . . . . in the bit stream.

Processor 210 may obtain the next 7 bits, 1001100, and may send the first 4 of these, 1001, to detectors 220. 1 is received by D₀ detector 220-0; 10 is received by D₁ detector 220-1; 100 is received by D₂ detector 220-2; and 1001 is received by D₃ detector 220-3. Only D₀ detector 220-0 detects the valid leading bit (without corresponding value bits). Processor 210 may compute code number, ((1<<0)−1)=0, and may advance the pointer by ((0<<1)+1)=1 bit to 0011001010 . . . .

Concluding by showing a third iteration in the example, processor 210 may obtain the next 7 bits, 0011001, and may send the first 4 of these, 0011, to detectors 220. 0 is received by D₀ detector 220-0; 00 is received by D₁ detector 220-1; 001 is received by D₂ detector 220-2; and 0011 is received by D₃ detector 220-3. Only D₂ detector 220-2 detects valid leading bits. In response, processor 210 may grab 2 value bits (i.e., 10) and compute the corresponding code number, 5. Processor 210 may advance the stream pointer to 01010 . . . . and continue decoding in a similar manner.

The foregoing description of one or more implementations provides illustration and description, but is not intended to be exhaustive or to limit the scope of the invention to the precise form disclosed. Modifications and variations are possible in light of the above teachings or may be acquired from practice of various implementations of the invention.

For example, although system 200 and process 400 have been described with regard to Exp-Golomb codes, these parallel hardware decoding schemes may be applied to any variable-length code. For example, the techniques described herein may be applied to decode Huffman codes or other types of variable-length codes.

Moreover, the acts in FIG. 4 need not be implemented in the order shown; nor do all of the acts necessarily need to be performed. Also, those acts that are not dependent on other acts may be performed in parallel with the other acts. Further, at least some of the acts in this figure may be implemented as instructions, or groups of instructions, implemented in a machine-readable medium.

No element, act, or instruction used in the description of the present application should be construed as critical or essential to the invention unless explicitly described as such. Also, as used herein, the article “a” is intended to include one or more items. Variations and modifications may be made to the above-described implementation(s) of the claimed invention without departing substantially from the spirit and principles of the invention. All such modifications and variations are intended to be included herein within the scope of this disclosure and protected by the following claims.

1. A system, comprising:
a plurality of detectors, each detector arranged to receive a different number of N leading bits and to output an affirmative feedback bit if the different number of N leading bits matches a respective predetermined pattern, N being an integer; and
a processor to provide the N leading bits to the plurality of detectors, to receive a corresponding plurality of feedback bits, and to determine an Exponential Golomb code number based on the plurality of feedback bits.

2. The system of claim 1, wherein the plurality of detectors includes N different detectors, and
wherein each of the N detectors is arranged to receive a first leading bit.

3. The system of claim 2, wherein (N-1) of the N detectors are arranged to receive a second leading bit in addition to the first leading bit.

4. The system of claim 3, wherein (N-2) of the N detectors are arranged to receive a third leading bit in addition to the first and second leading bits.

5. The system of claim 1, wherein the feedback bits designate a number of the N leading bits as valid leading bits, and
wherein the processor is arranged to designate a number of bits following the valid leading bits as value bits.

6. The system of claim 5, wherein the processor is further arranged to determine the Exponential Golomb code number from the number of valid leading bits and the value bits.

7. The system of claim 1, wherein the processor is further arranged to increment a pointer to a beginning of a next Exponential Golomb code word based on the feedback bits.

8. A decoder to find valid leading bits of an Exponential Golomb code, comprising:
a first detector to output a first feedback bit based on a first leading bit;
a second detector to output a second feedback bit based on the first leading bit and a second leading bit; and
a third detector to output a third feedback bit based on the first leading bit, the second leading bit, and a third leading bit,
wherein the first, second, and third feedback bits designate which of the first, second, and third detectors received the valid leading bits of the Exponential Golomb code.

9. The decoder of claim 8, further comprising:
an nth detector to output an nth feedback bit based on first through nth leading bits, n being an integer greater than three.

10. The decoder of claim 8, wherein the first feedback bit is one when the first leading bit is one,
wherein the second feedback bit is one when the second leading bit is one and when the first leading bit is zero, and
wherein the third feedback bit is one when the third leading bit is one and when the second leading bit and the first leading bit are zero.

11. The decoder of claim 8, wherein the first feedback bit is zero when the first leading bit is zero,
wherein the second feedback bit is zero when the second leading bit is zero or when the first leading bit is one, and
wherein the third feedback bit is zero when the third leading bit is zero or when the second leading bit is one or when the first leading bit is one.

12. The decoder of claim 8, wherein only one of the feedback bits has a value of one, the one feedback bit corresponding to the detector that received the valid leading bits.

13. A method, comprising:
sending data from a pointer location in a bit stream to parallel detectors;
receiving feedback bits from the parallel detectors;
computing an Exponential Golomb code number from the feedback bits; and
advancing the pointer location in the bit stream based on the feedback bits.

14. The method of claim 13, wherein the sending includes:
sending the first N bits from the pointer location, N being a maximum leading bit length for an Exponential Golomb code having a maximum length of M bits, N and M being integers.

15. The method of claim 14, wherein the receiving includes:
receiving N feedback bits from the parallel detectors, one of the N feedback bits having a value of one and others of the N feedback bits having a value of zero.

16. The method of claim 13, wherein the computing includes:
determining a code word including one or more leading bits and zero or more value bits from the feedback bits.

17. The method of claim 16, wherein the computing further includes:
bit-shifting by a value of the leading bits and adding the zero or more value bits to obtain the code number.

18. The method of claim 16, wherein the advancing includes:
bit-shifting the leading bits by one and adding one to determine a number of bits to advance the pointer location.

19. A system, comprising:
logic to send N bits after a pointer location in a bit stream to a decoder, to receive N result bits from the decoder, and to determine a length of a code word after the pointer location based on the N result bits, N being an integer; and
the decoder including:
a first detector arranged to receive a first bit of the N bits and to output a first result bit of the N result bits based on the first bit, and
a second detector arranged to receive the first bit and a second bit of the N bits and to output a second result bit of the N result bits based on the first bit and the second bit.

20. The system of claim 19, wherein the logic is further arranged to determine an Exponential Golomb code number from the code word defined by the length of the code word after the pointer location.

21. The system of claim 20, wherein the logic is further arranged to output the Exponential Golomb code number.

22. The system of claim 19, wherein the logic is further arranged to increment the pointer location by the length of the code word.

23. The system of claim 19, wherein the logic determines the length of the code word by bit-shifting by one bit an amount corresponding to an address of an affirmative result bit and adding one to a result of the bit-shifting.

24. The system of claim 19, wherein the decoder further includes:
a third detector arranged to receive the first bit, the second bit, and a third bit of the N bits and to output a third result bit of the N result bits based on the first bit, the second bit, and the third bit.
